(19) United States
(12) Patent Application Publication
(10) Pub. No.: US 2024/0297097 A1
(43) Pub. Date: Sep. 5, 2024

(54) HEAT RADIATING MEMBER AND COOLING DEVICE

(71) Applicant: NIDEC CORPORATION, Kyoto (JP)

(72) Inventor: Kazuhiro NISHIKAWA, Kyoto (JP)

(21) Appl. No.: 18/587,967

(22) Filed: Feb. 27, 2024

(30) Foreign Application Priority Data
Mar. 1, 2023 (JP) 2023-030639

(51) Int. Cl. H01L 23/473

(52) U.S. Cl. CPC H01L 23/473

(57) ABSTRACT

A fin includes spoilers along a first direction. Each spoiler protrudes in a second direction only at one position on a periphery of an opening passing through a side plate part in the second direction, and is inclined to a first side in the first direction that is a downstream side and a second side in the third direction. An upstream spoiler includes a first end on the second side in the first direction. The first end includes, on the second side in the third direction, a second end on the first side from a center of the side plate part in the third direction. A part of at least one downstream spoiler is on the second side in the third direction from a fourth end on the second side in the third direction of a third end on the second side in the first direction of the upstream spoiler.

### CROSS-REFERENCE TO RELATED APPLICATIONS

The present invention claims priority under 35 U.S.C. § 119 to Japanese Patent Application No. 2023-030639 filed on Mar. 1, 2023, the entire content of which is incorporated herein by reference.

### FIELD OF THE INVENTION

The present disclosure relates to a heat radiating member.

### BACKGROUND

Heat radiating members are conventionally used for cooling heating elements. The heat radiating members each includes a base part and a plurality of fins. The plurality of fins protrudes from the base part. When a refrigerant such as water flows between adjacent fins in the plurality of fins, heat of the heating element moves to the refrigerant.

The heat radiating member includes the base part that is provided on its bottom surface side (a side opposite to the fins) with the heating element, so that a base part side has a high temperature. Thus, cooling performance on the base part side is to be improved to improve cooling efficiency.

### SUMMARY

An exemplary heat radiating member according to the present disclosure includes a base part in a plate shape extending in a first direction along a direction in which a refrigerant flows and in a second direction orthogonal to the first direction and having a thickness in a third direction orthogonal to the first direction and the second direction, and a fin protruding from the base part toward a first side in the third direction and extending in the first direction. The fin includes a side plate part extending in the first direction and the third direction and having a thickness in the second direction, and a plurality of spoilers disposed along the first direction. Each of the plurality of spoilers protrudes in the second direction only at one position on a periphery of an opening provided passing through the side plate part in the second direction, and is inclined to a first side in the first direction that is a downstream side and a second side in the third direction. The plurality of spoilers includes one upstream spoiler and at least one downstream spoiler disposed on the first side in the first direction from the one upstream spoiler. The upstream spoiler includes a first end on the second side in the first direction, the first end including a second end on the second side in the third direction, the second end being located on the first side in the third direction from a center position of the side plate part in the third direction. At least a part of the at least one downstream spoiler is located on the second side in the third direction from a fourth end on the second side in the third direction of a third end on the second side in the first direction of the upstream spoiler.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a heat radiating member according to an exemplary embodiment of the present disclosure;

FIG. 2 is a perspective view illustrating a state in which some fins are removed from a heat radiating member;

FIG. 3 is a side view of a heat radiating member in the state illustrated in FIG. 2 as viewed from the first side in the second direction;

FIG. 4 is a perspective view illustrating a partial structure of a fin on the first side (downstream side) in the first direction;

FIG. 5 is a side view of a part of the heat radiating member on the downstream side in the state of FIG. 2 as viewed from the first side in the second direction;

FIG. 6 is a diagram illustrating a positional relationship of an upstream spoiler;

FIG. 7 is a side view of a part of the heat radiating member on the downstream side in the state of FIG. 2 as viewed from the first side in the second direction;

FIG. 8 is a side view of a part of the heat radiating member on the downstream side in the state of FIG. 2 as viewed from the first side in the second direction;

FIG. 9 is a side view of a part of the heat radiating member on the downstream side in the state of FIG. 2 as viewed from the first side in the second direction;

FIG. 10 is a side view of a part of the heat radiating member on the downstream side in the state of FIG. 2 as viewed from the first side in the second direction; and

FIG. 11 is a partial side sectional view of a cooling device including a heat radiating member.

### DETAILED DESCRIPTION

Hereinafter, an exemplary embodiment of the present disclosure will be described with reference to the drawings.

The drawings each indicate a first direction as an X direction in which X1 indicates a first side in the first direction and X2 indicates a second side in the first direction. The first direction is along a direction F in which a refrigerant W flows, and F1 indicates a downstream side and F2 indicates an upstream side. The first direction is orthogonal to a second direction as a Y direction in which Y1 indicates a first side in the second direction, and Y2 indicates a second side in the second direction. The first direction and the second direction are orthogonal to a third direction as a Z direction in which Z1 indicates a first side in the third direction, and Z2 indicates a second side in the third direction. The above-described orthogonal also includes intersection at an angle slightly shifted from 90 degrees. Each of the above directions does not limit a direction when the heat radiating member and the cooling device are incorporated in various devices.

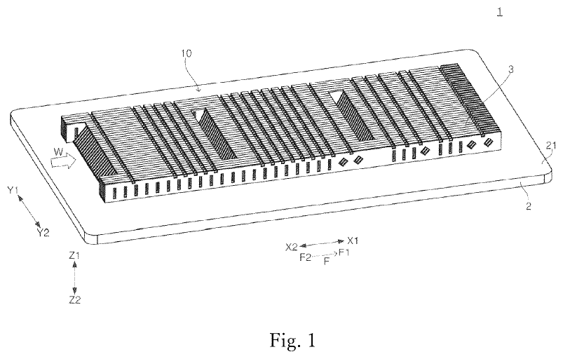

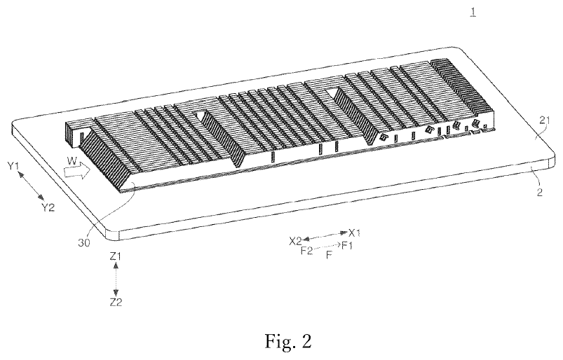

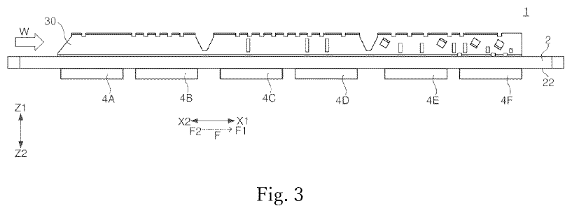

FIG. 1 is a perspective view of a heat radiating member 1 according to an exemplary embodiment of the present disclosure. FIG. 2 is a perspective view illustrating a state in which some fins are removed from the heat radiating member 1. FIG. 3 is a side view of the heat radiating member 1 in the state illustrated in FIG. 2 as viewed from the first side in the second direction. However, FIG. 3 also illustrates heating elements 4A, 4B, 4C, 4D, 4E, and 4F (referred to below as 4A and the like) to be cooled by the heat radiating member 1.

The heat radiating member 1 is a device that cools the plurality of heating elements 4A and the like disposed in the first direction. The heating elements 4A and the like are power transistors of an inverter provided in a traction motor for driving wheels of a vehicle, for example. The power transistor is, for example, an insulated gate bipolar transistor (IGBT). In this case, the heat radiating member 1 is mounted on the traction motor. The number of heating elements may be a plural number other than six, or may be singular.

The heat radiating member 1 includes a base part 2 and a heat radiating fin part 10.

The base part 2 has a plate shape that extends in the first direction and the second direction and has a thickness in the third direction. The base part 2 is made of a metal having high thermal conductivity, such as a copper plate.

The heat radiating fin part 10 is formed as a so-called stacked fin by disposing a plurality of fins 3 in the second direction. One fin 3 is formed of a metal plate extending in the first direction, and formed of a copper plate, for example. The heat radiating fin part 10 is fixed to a surface 21 of the base part 2 on the first side in the third direction by brazing, for example. That is, the heat radiating member 1 includes the fin 3 protruding from the base part 2 toward the first side in the third direction and extending in the first direction.

FIG. 2 illustrates a state in which a part including the plurality of fins 3 on the second side in the second direction in the heat radiating fin part 10 is removed, and a fin 30 is located most outward on the second side in the second direction in the removed state. FIG. 1 illustrates the heat radiating member 1 in which the fins 3 different in shape depending on a second direction position are used, but all the fins 3 to be used may be identical in shape. Detailed structure of the fin 30 will be described later.

The heating elements 4A and the like are in direct or indirect contact with a surface 22 of the base part 2 on the second side in the third direction (see FIG. 3). When viewed in the third direction, each of the heating elements 4A and the like overlaps the heat radiating fin part 10.

When the refrigerant W is supplied to the heat radiating fin part 10 from the upstream side of the heat radiating fin part 10, the refrigerant W flows toward the first side in the first direction in a space between the fins 3 adjacent to each other in the second direction, and then heat generated by the heating elements 4A and the like moves to the refrigerant W through the base part 2 and the fins 3. As a result, the heating elements 4A and the like are cooled.

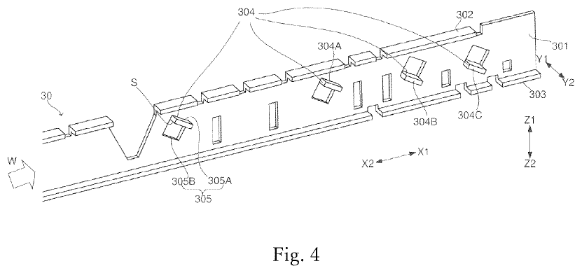

Here, the structure of the fin 30 will be described with reference to FIG. 4. FIG. 4 is a perspective view illustrating a partial structure of the fin 30 on the first side (downstream side) in the first direction. As illustrated in FIG. 4, the fin 30 includes a side plate part 301 extending in the first direction and the third direction and having a thickness in the second direction. The fin 30 also includes a top plate part 302 formed by bending a first end of the side plate part 301 on the first side in the third direction toward the second side in the second direction, and a bottom plate part 303 formed by bending a second end of the side plate part 301 on the second side in the third direction toward the second side in the second direction. The top plate part 302 and the bottom plate part 303 are each divided along the first direction in FIG. 4, but are not each necessarily divided. The bottom plate part 303 is fixed to the surface 21 of the base part 2 on the first side in the third direction. The refrigerant W flows along the side plate part 301, the top plate part 302, and the bottom plate part 303.

As illustrated in FIG. 4, the side plate part 301 is provided with an opening 305 passing through the side plate part 301 in the second direction. The opening 305 has a rectangular shape. The opening 305 has four sides constituting its periphery, the four sides including sides 305A and 305B inclined toward the first side in the first direction and the second side in the third direction. The side 305A is located on the first side in the third direction from the side 305B.

The spoiler 304 is formed by being bent toward the second side in the second direction on at least one of the side 305A and the side 305B. The spoiler 304 can be formed by cutting a part of the side plate part 301 and bending the part. The spoiler 304 is inclined toward the first side in the first direction and the second side in the third direction. The spoiler provided protruding from only one of the sides 305A and 305B is called a single spoiler. FIG. 4 illustrates four spoilers 304 that are each the single spoiler. A set of spoilers provided protruding from both of the sides 305A and 305B toward the second side in the second direction is called a double spoiler.

The spoiler 304 includes an opposing surface S facing a direction in which the refrigerant W flows, or the first side in the first direction. The spoiler 304 has a function of interrupting a flow of the refrigerant W using the opposing surface S. This function facilitates generation of a turbulent flow of the refrigerant W near the opposing surface S, and thus cooling performance using the fin 3 can be improved.

Here, the spoiler 304 will be described by focusing on spoilers 304A, 304B, and 304C on the most downstream side. The spoilers 304A, 304B, and 304C are each a single spoiler. That is, the fin 30 includes the plurality of spoilers 304A, 304B, and 304C disposed along the first direction. Each of the plurality of spoilers 304A, 304B, and 304C protrudes in the second direction only at one position on the periphery of the opening 305 provided passing through the side plate part 301 in the second direction, and is inclined to the first side in the first direction and the second side in the third direction.

Hereinafter, the spoiler 304A is referred to as an upstream spoiler 304A, and the spoilers 304B and 304C are referred to as downstream spoilers 304B and 304C. The number of downstream spoilers may be three or more, or may be singular. That is, the plurality of spoilers 304A, 304B, and 304C includes one upstream spoiler 304A and at least one downstream spoiler 304B or 304C disposed on the first side in the first direction from the upstream spoiler 304A.

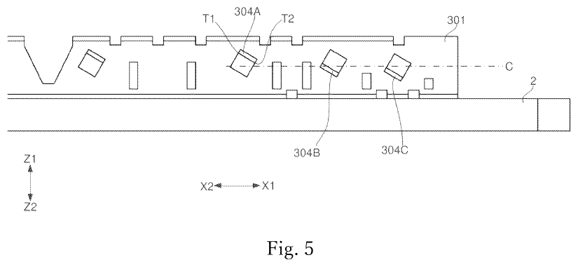

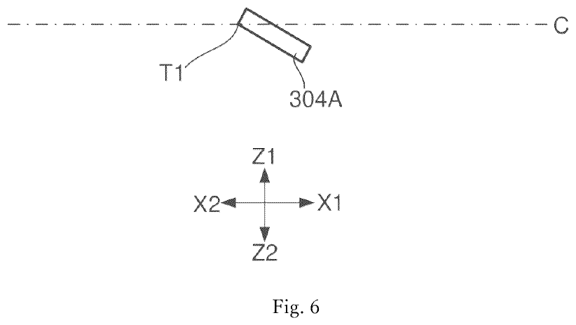

FIG. 5 is a side view of a part of the heat radiating member 1 on the downstream side in the state of FIG. 2 as viewed from the first side in the second direction. As illustrated in FIG. 5, the upstream spoiler 304A includes a second end on the second side in the first direction (an upstream end), the second end including an end T1 on the second side in the third direction, the end T1 being located on the first side in the third direction with respect to a center position C of the side plate part 301 in the third direction. The end T1 on the second side in the third direction may be located on the first side in the third direction from a state in which the end T1 is located at the center position C in the third direction as illustrated in FIG. 6.

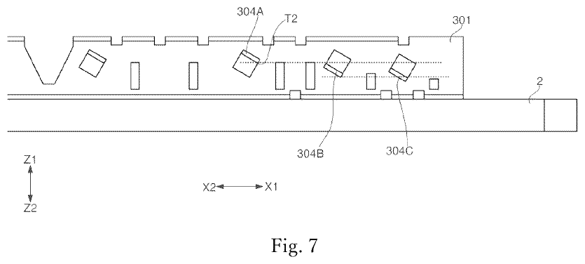

FIG. 7 is a side view as with FIG. 5. As illustrated in FIG. 7, all of the downstream spoilers 304B and 304C are located on the second side in the third direction from an end T2 on the second side in the third direction of a third end on the first side in the first direction (a downstream end) of the upstream spoiler 304A. For example, the downstream spoiler 304B may be displaced toward the first side in the third direction from the position in FIG. 7 to locate a part of the downstream spoiler 304B on the second side in the third direction from the end T2 on the second side in the third direction. That is, at least a part of all the downstream spoilers 304B and 304C are located on the second side in the third direction from the end T2 on the second side in the third direction of the third end on the first side in the first direction of the upstream spoiler 304A.

The spoiler 304 has a function of diverting the refrigerant toward the first side in the third direction (toward a side opposite to the base part 2) and the second side in the third direction (toward the base part 2). Then, when the upstream spoiler 304A disposed on the most upstream side among the plurality of spoilers 304A, 304B, 304C has the above positional relationship with respect to the center position C in the third direction, the amount of the refrigerant diverted toward the first side in the third direction can be reduced and the refrigerant W can be more drawn toward the second side in the third direction. The refrigerant W pressed toward the second side in the third direction by the upstream spoiler 304A can be pressed toward the second side in the third direction again by the downstream spoilers 304B and 304C. The second side in the third direction close to the base part 2 has a high temperature, so that cooling efficiency is improved by pressing the refrigerant toward the second side in the third direction. The spoilers 304A, 304B, and 304C are each a single spoiler. Although a double spoiler with spoilers formed on opposite sides of one opening has a structure in which the spoilers are close to each other and thus are likely to cause a turbulent flow, the single spoiler has a high effect of pressing the refrigerant toward the second side in the third direction.

As illustrated in FIG. 5, the end T2 on the second side in the third direction of the third end on the first side in the first direction of the upstream spoiler 304A is located on the first side in the third direction with respect to the center position C in the third direction. This structure enables the upstream spoiler 304A to draw more refrigerant W toward the second side in the third direction.

As illustrated in FIG. 7, all of at least one of the downstream spoilers 304B and 304C are located on the second side in the third direction from the end T2 on the second side in the third direction of the third end on the first side in the first direction of the upstream spoiler 304A. This structure allows the downstream spoilers 304B and 304C to have an increased effect of pressing the refrigerant W toward the second side in the third direction.

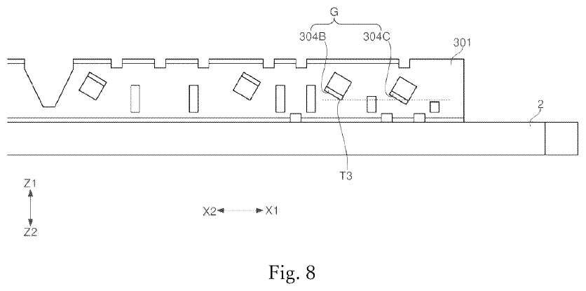

FIG. 8 is a side view as with FIG. 5. As illustrated in FIG. 8, a part of the downstream spoiler 304C is located on the second side in the third direction from an end T3 on the second side in the third direction of a third end on the first side in the first direction of the downstream spoiler 304B. All of the downstream spoiler 304C may be located on the second side in the third direction with respect to the end T3 on the second side in the third direction.

That is, a plurality of downstream spoilers 304B and 304C is provided. The plurality of downstream spoilers 304B and 304C includes at least one downstream spoiler set G including a first downstream spoiler 304B on the second side in the first direction and a second downstream spoiler 304C on the first side in the first direction, which are disposed adjacent to each other in the order along the first direction. At least any one of downstream spoiler sets G includes the second downstream spoiler 304C with at least a part located on the second side in the third direction with respect to the end T3 on the second side in the third direction of the third end on the first side in the first direction of the first downstream spoiler 304B. This structure enables the effect of pressing the refrigerant W toward the second side in the third direction to be increased toward the downstream side. Such a structure is desirable because the refrigerant W is increased in temperature toward the downstream side.

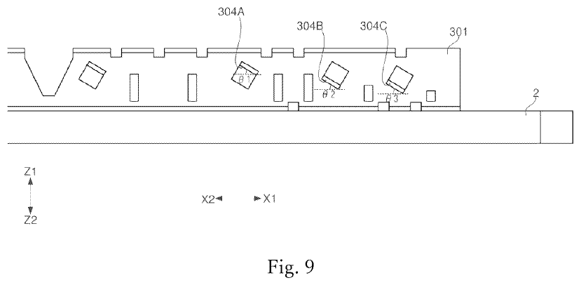

FIG. 9 is a side view as with FIG. 5. As illustrated in FIG. 9, the spoilers 304A, 304B, and 304C form angles θ1, θ2, and θ3 from the first direction, respectively, the angles being each 45 degrees or less. That is, at least any one of the plurality of spoilers 304A, 304B, and 304C, and the first direction, form an angle of 45 degrees or less. This structure enables the effect of pressing the refrigerant W toward the second side in the third direction to be achieved while suppressing pressure loss due to a turbulent flow generated by the spoilers 304A, 304B, and 304C.

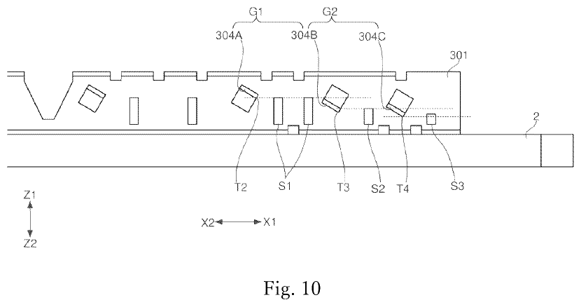

FIG. 10 is a side view as with FIG. 5. As illustrated in FIG. 10, a spoiler set G1 includes the upstream spoiler 304A and the downstream spoiler 304B. Between the upstream spoiler 304A and the downstream spoiler 304B in the first direction, a slit S1 is provided. The downstream spoiler 304B and the downstream spoiler 304C constitute a spoiler set G2. Between the downstream spoiler 304B and the downstream spoiler 304C in the first direction, a slit S2 is provided. The downstream spoiler 304C is provided on the first side in the first direction with a slit S3. The slits S1, S2, and S3 are provided passing through the side plate part 301 in the second direction.

All of the slit S1 is located more on the second side in the third direction than the end T2 on the second side in the third direction of the third end on the first side in the first direction of the upstream spoiler 304A immediately upstream of the slit S1. All of the slit S2 is located more on the second side in the third direction than the end T3 on the second side in the third direction of the third end on the first side in the first direction of the downstream spoiler 304B immediately upstream of the slit S2. A part of the slit S3 is located more on the second side in the third direction than an end T4 on the second side in the third direction of a third end on the first side in the first direction of the downstream spoiler 304C immediately upstream of the slit S3.

Providing the slits S1, S2, and S3 causes a boundary layer of a flow developed in the side plate part 301 to be destroyed and a turbulent flow to be promoted, so that the cooling efficiency is improved.

That is, the plurality of spoilers 304A, 304B, and 304C includes at least one of the spoiler sets G1 and G2 including a first spoiler on the second side in the first direction and a second spoiler on the first side in the first direction, which are disposed adjacent to each other in the order along the first direction. At least one of the slits S1, S2, and S3 passing through the side plate part 301 in the second direction is provided at least in a space between the first spoiler and the second spoiler in the first direction or on the first side in the first direction from the second spoiler disposed on the most first side in the first direction in at least one of the spoiler sets G1 and G2. At least a part of the slits S1, S2, and S3 is located on the second side in the third direction from a second end on the second side in the third direction of a third end on the first side in the first direction of the spoiler disposed closest to the slit on the second side in the first direction of the slit. This structure allows the refrigerant W to flow into the slits S1, S2, and S3 each having cooling performance while the flow of the refrigerant W is concentrated by the first spoiler on the upstream side, so that the cooling performance can be further improved.

All of at least any one of the slits S1 and S2 is located on the second side in the third direction from the ends T2 and T3 on the second side in the third direction of the corresponding third ends on the first side in the first direction of the spoilers 304A and 304B disposed close to the corresponding slits. This structure causes the slits S1 and S2 not to be provided on the first side in the third direction from the ends T2 and T3 on the second side in the third direction of the corresponding third ends on the first side in the first direction of the spoilers 304A and 304B, so that the pressure loss due to a turbulent flow can be suppressed.

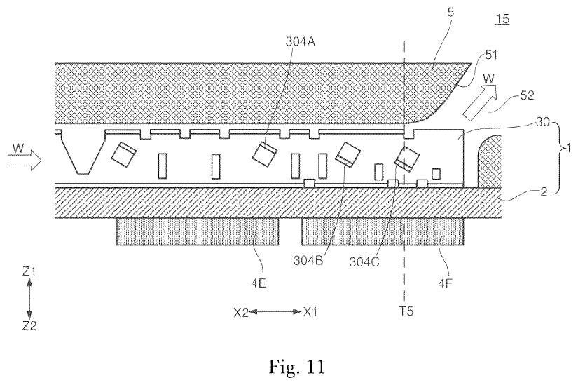

FIG. 11 is a partial side sectional view of a cooling device 15 including the heat radiating member 1. FIG. 11 illustrates a structure of the heat radiating member 1 on the most downstream side. The cooling device 15 includes the heat radiating member 1 and a liquid cooling jacket 5 in which the heat radiating member 1 is installed.

The liquid cooling jacket 5 and the heat radiating member 1 surround a space in which the refrigerant W flows. The liquid cooling jacket 5 includes an outlet-side flow path 52. The outlet-side flow path 52 is formed along a wall surface 51 provided in the liquid cooling jacket 5. The wall surface 51 is inclined toward the first side in the first direction and the first side in the third direction. That is, the wall surface 51 extends in a direction in which a component on the first side in the first direction and a component on the first side in the third direction are combined. Alternatively, the wall surface 51 may be formed extending in a direction including no component in the first direction and the component on the first side in the third direction (upward on the paper surface of FIG. 11). That is, the liquid cooling jacket 5 includes the outlet-side flow path 52 provided along the wall surface 51 extending in the direction having the component on the first side in the third direction.

As illustrated in FIG. 11, a part of the heating element 4F on the most downstream side is located on the first side in the first direction from an end T5 of the wall surface 51, the end T5 being on the second side in the first direction. All of the heating element 4F may be located on the first side in the first direction from the end T5 on the second side in the first direction. That is, the heating element 4F can be installed on the second side in the third direction from the base part 2, the heating element 4F being at least partially disposed on the first side in the first direction from the end T5 on the second side in the first direction of the wall surface 51.

FIG. 11 illustrates the spoilers 304A, 304B, and 304C in which the downstream spoilers 304B and 304C are disposed on the first side in the third direction from the heating element 4F. Alternatively, the upstream spoiler 304A and the downstream spoilers 304B and 304C may be disposed on the first side in the third direction from the heating element 4F, or only the downstream spoiler 304C may be disposed on the first side in the third direction from the heating element 4F. That is, at least the spoiler 304C on the most first side in the first direction among the plurality of spoilers 304A, 304B, 304C is disposed on the first side in the third direction from the heating element 4F.

Although the outlet-side flow path 52 allows the refrigerant W to easily flow toward the first side in the third direction on the most downstream side, a flow of the refrigerant W toward the first side in the third direction is suppressed by at least the spoiler 304C, and thus the refrigerant W is guided to near the heating element 4F on the most downstream side. As a result, a temperature rise of the heating element 4F can be suppressed.

The spoilers 304A, 304B, and 304C described above may be provided not only on the most downstream side but also on a more upstream side than the most downstream side in the heat radiating member 1.

The embodiment of the present disclosure has been described above. The scope of the present disclosure is not limited to the above embodiment. The present disclosure can be implemented by making various changes to the above embodiment without departing from the gist of the invention. The matters described in the above embodiment can be optionally combined together, as appropriate, as long as there is no inconsistency.

As described above, a heat radiating member according to an aspect of the present disclosure includes: a base part in a plate shape extending in a first direction along a direction in which a refrigerant flows and in a second direction orthogonal to the first direction and having a thickness in a third direction orthogonal to the first direction and the second direction; and a fin protruding from the base part toward a first side in the third direction and extending in the first direction, the fin including: a side plate part extending in the first direction and the third direction and having a thickness in the second direction; and a plurality of spoilers disposed along the first direction, each of the plurality of spoilers protruding in the second direction only at one position on a periphery of an opening provided passing through the side plate part in the second direction, and being inclined to a first side in the first direction that is a downstream side and a second side in the third direction, the plurality of spoilers including one upstream spoiler and at least one downstream spoiler disposed on the first side in the first direction from the one upstream spoiler, the upstream spoiler including a first end on the second side in the first direction, the first end including a second end on the second side in the third direction, the second end being located on the first side in the third direction from a center position of the side plate part in the third direction, and at least a part of the at least one downstream being located on the second side in the third direction from a fourth end on the second side in the third direction of a third end on the second side in the first direction of the upstream spoiler (first structure).

The first structure may be configured such that the fourth end on the second side in the third direction of the third end on the first side in the first direction of the upstream spoiler is located on the first side in the third direction from the center position in the third direction (second structure).

The first or second structure may be configured such that all of at least one of the downstream spoilers is located on the second side in the third direction from the fourth end on the second side in the third direction of the third end on the first side in the first direction of the upstream spoiler (third structure).

Any one of the first to third structures may be configured such that a plurality of the downstream spoilers is provided, the plurality of downstream spoilers includes at least one downstream spoiler set including a first downstream spoiler on the second side in the first direction and a second downstream spoiler on the first side in the first direction, the first downstream spoiler and the second downstream spoiler being disposed adjacent to each other in an order along the first direction, and at least any one of the downstream spoiler sets includes the second downstream spoiler with at least a part that is located on the second side in the third direction from a fourth end on the second side in the third direction of a third end on the first side in the first direction of the first downstream spoiler (fourth structure).

Any one of the first to fourth structures may be configured such that at least any one of the plurality of spoilers and the first direction form an angle of 45 degrees or less (fifth structure).

Any one of the first to fifth structures may be configured such that the plurality of spoilers includes at least one spoiler set including a first spoiler on the second side in the first direction and a second spoiler on the first side in the first direction, the first spoiler and the second spoiler being disposed adjacent to each other in the order along the first direction, at least one slit passing through the side plate part in the second direction is provided at least in a space between the first spoiler and the second spoiler in the first direction or on the first side in the first direction from the second spoiler disposed on the most first side in the first direction in at least one of the spoiler sets, and at least a part of the slit is located on the second side in the third direction from a fourth end on the second side in the third direction of a third end on the first side in the first direction of the spoiler disposed closest to the slit on the second side in the first direction of the slit (sixth structure).

The sixth structure may be configured such that all of at least any one of the slits is located on the second side in the third direction from the fourth end on the second side in the third direction of the third end on the first side in the first direction of the spoiler disposed close to the slit (seventh structure).

A cooling device according to an aspect of the present disclosure includes: the heat radiating member having any one of the first to seventh structures; and a liquid cooling jacket in which the heat radiating member is installed, the liquid cooling jacket including an outlet-side flow path provided along a wall surface extending in a direction including a component on the first side in the third direction, wherein a heating element with at least a part disposed on the first side in the first direction from an end of the wall surface, the end being on the second side in the first direction, is installed on the base part on the second side in the third direction, and at least the spoiler on the most first side in the first direction among the plurality of spoilers is disposed on the first side in the third direction from the heating element (eighth configuration).

The technique of the present disclosure can be used for cooling various heating elements, for example.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A heat radiating member comprising:
a base part in a plate shape extending in a first direction along a direction in which a refrigerant flows and in a second direction orthogonal to the first direction and having a thickness in a third direction orthogonal to the first direction and the second direction; and
a fin protruding from the base part toward a first side in the third direction and extending in the first direction,
the fin including:
a side plate part extending in the first direction and the third direction and having a thickness in the second direction; and
a plurality of spoilers disposed along the first direction, each of the plurality of spoilers protruding in the second direction only at one position on a periphery of an opening provided passing through the side plate part in the second direction, and being inclined to a first side in the first direction that is a downstream side and a second side in the third direction,
the plurality of spoilers including one upstream spoiler and at least one downstream spoiler disposed on the first side in the first direction from the one upstream spoiler,
the upstream spoiler including a first end on the second side in the first direction, the first end including a second end on the second side in the third direction, the second end being located on the first side in the third direction from a center position of the side plate part in the third direction, and
at least a part of the at least one downstream being located on the second side in the third direction from a fourth end on the second side in the third direction of a third end on the second side in the first direction of the upstream spoiler.

2. The heat radiating member according to claim 1, wherein
the fourth end on the second side in the third direction of the third end on the first side in the first direction of the upstream spoiler is located on the first side in the third direction from the center position in the third direction.

3. The heat radiating member according to claim 1, wherein all of at least one of the downstream spoilers is located on the second side in the third direction from the fourth end on the second side in the third direction of the third end on the first side in the first direction of the upstream spoiler.

4. The heat radiating member according to claim 1, wherein
a plurality of the downstream spoilers is provided,
the plurality of downstream spoilers includes at least one downstream spoiler set including a first downstream spoiler on the second side in the first direction and a second downstream spoiler on the first side in the first direction, the first downstream spoiler and the second downstream spoiler being disposed adjacent to each other in an order along the first direction, and
at least any one of the downstream spoiler sets includes the second downstream spoiler with at least a part that is located on the second side in the third direction from a fourth end on the second side in the third direction of a third end on the first side in the first direction of the first downstream spoiler.

5. The heat radiating member according to claim 1, wherein
at least any one of the plurality of spoilers and the first direction form an angle of 45 degrees or less.

6. The heat radiating member according to claim 1, wherein
the plurality of spoilers includes at least one spoiler set including a first spoiler on the second side in the first direction and a second spoiler on the first side in the first direction, the first spoiler and the second spoiler being disposed adjacent to each other in the order along the first direction,
at least one slit passing through the side plate part in the second direction is provided at least in a space between the first spoiler and the second spoiler in the first direction or on the first side in the first direction from the second spoiler disposed on the most first side in the first direction in at least one of the spoiler sets, and
at least a part of the slit is located on the second side in the third direction from a fourth end on the second side in the third direction of a third end on the first side in the first direction of the spoiler disposed closest to the slit on the second side in the first direction of the slit.

7. The heat radiating member according to claim 6, wherein
all of at least any one of the slits is located on the second side in the third direction from the fourth end on the second side in the third direction of the third end on the first side in the first direction of the spoiler disposed close to the slit.

8. A cooling device comprising:
the heat radiating member according to claim 1; and
a liquid cooling jacket in which the heat radiating member is installed,
the liquid cooling jacket including an outlet-side flow path provided along a wall surface extending in a direction including a component on the first side in the third direction,
wherein a heating element with at least a part disposed on the first side in the first direction from an end of the wall surface, the end being on the second side in the first direction, is installed on the base part on the second side in the third direction, and
at least the spoiler on the most first side in the first direction among the plurality of spoilers is disposed on the first side in the third direction from the heating element.
